(19) United States
(12) Patent Application Publication
(10) Pub. No.: US 2018/0175005 A1
(43) Pub. Date: Jun. 21, 2018

(54) THERMAL DISSIPATION USING ANISOTROPIC CONDUCTIVE MATERIAL

(71) Applicant: Intel Corporation, Santa Clara, CA (US)

(72) Inventor: Hyoung IL Kim, Folsom, CA (US)

(21) Appl. No.: 15/386,802

(22) Filed: Dec. 21, 2016

(51) Int. Cl. H01L 25/065; H01L 25/00; H01L 23/00

(52) U.S. Cl. CPC H01L 25/0657; H01L 25/50; H01L 24/32; H01L 2225/06517; H01L 2224/3201; H01L 2225/06589; H01L 2225/06548; H01L 2224/32501; H01L 2225/06527

(57) ABSTRACT

Various embodiments disclosed relate to an integrated circuit package. The integrated circuit package includes a substrate. A first die is attached to the substrate. The integrated circuit package further includes a second die. A thermally conductive layer is disposed between the first die and the second die. A first thermal conductivity of the layer in a first direction is greater than a second thermal conductivity of the layer in a second direction.

### BACKGROUND

In chip packages, components such as dies may reach elevated temperatures during operation. This may be problematic if certain components reach temperatures that are above the operating temperature of other components. Over time, exposure to these temperatures may cause certain components to fail.

### BRIEF DESCRIPTION OF THE FIGURES

In the drawings, which are not necessarily drawn to scale, like numerals describe substantially similar components throughout the several views. The drawings illustrate generally, by way of example, but not by way of limitation, various embodiments discussed in the present document.

FIG. 1 illustrates an example integrated circuit package, according to various embodiments.

FIG. 2 is a flow diagram illustrating a method of making the integrated circuit package.

FIG. 3 illustrates an example computer device that may employ the apparatuses and/or methods described herein.

### DETAILED DESCRIPTION

Reference will now be made in detail to certain embodiments of the disclosed subject matter, examples of which are illustrated in part in the accompanying drawings. While the disclosed subject matter will be described in conjunction with the enumerated claims, it will be understood that the exemplified subject matter is not intended to limit the claims to the disclosed subject matter.

Throughout this document, values expressed in a range format should be interpreted in a flexible manner to include not only the numerical values explicitly recited as the limits of the range, but also to include all the individual numerical values or sub-ranges encompassed within that range as if each numerical value and sub-range is explicitly recited. For example, a range of “about 0.1% to about 5%” or “about 0.1% to 5%” should be interpreted to include not just about 0.1% to about 5%, but also the individual values (e.g., 1%, 2%, 3%, and 4%) and the sub-ranges (e.g., 0.1% to 0.5%, 1.1% to 2.2%, 3.3% to 4.4%) within the indicated range. The statement “about X to Y” has the same meaning as “about X to about Y,” unless indicated otherwise. Likewise, the statement “about X, Y, or about Z” has the same meaning as “about X, about Y, or about Z,” unless indicated otherwise.

In this document, the terms “a,” “an,” or “the” are used to include one or more than one unless the context clearly dictates otherwise. The term “or” is used to refer to a nonexclusive “or” unless otherwise indicated. The statement “at least one of A and B” has the same meaning as “A, B, or A and B.” In addition, it is to be understood that the phraseology or terminology employed herein, and not otherwise defined, is for the purpose of description only and not of limitation. Any use of section headings is intended to aid reading of the document and is not to be interpreted as limiting; information that is relevant to a section heading may occur within or outside of that particular section.

In the methods described herein, the acts may be carried out in any order without departing from the principles of the inventive subject matter, except when a temporal or operational sequence is explicitly recited. Furthermore, specified acts may be carried out concurrently unless explicit claim language recites that they be carried out separately. For example, a claimed act of doing X and a claimed act of doing Y may be conducted simultaneously within a single operation, and the resulting process will fall within the literal scope of the claimed process.

The term “about” as used herein may allow for a degree of variability in a value or range, for example, within 10%, within 5%, or within 1% of a stated value or of a stated limit of a range, and includes the exact stated value or range.

The term “substantially” as used herein refers to a majority of, or mostly, as in at least about 50%, 60%, 70%, 80%, 90%, 95%, 96%, 97%, 98%, 99%, 99.5%, 99.9%, 99.99%, or at least about 99.999% or more, or 100%.

As used herein, the term “circuitry” may refer to, be part of, or include an Application Specific Integrated Circuit (ASIC), an electronic circuit, a processor (shared, dedicated, or group) and/or memory (shared, dedicated, or group) that execute one or more software or firmware programs, a combinational logic circuit, and/or other suitable components that provide the described functionality.

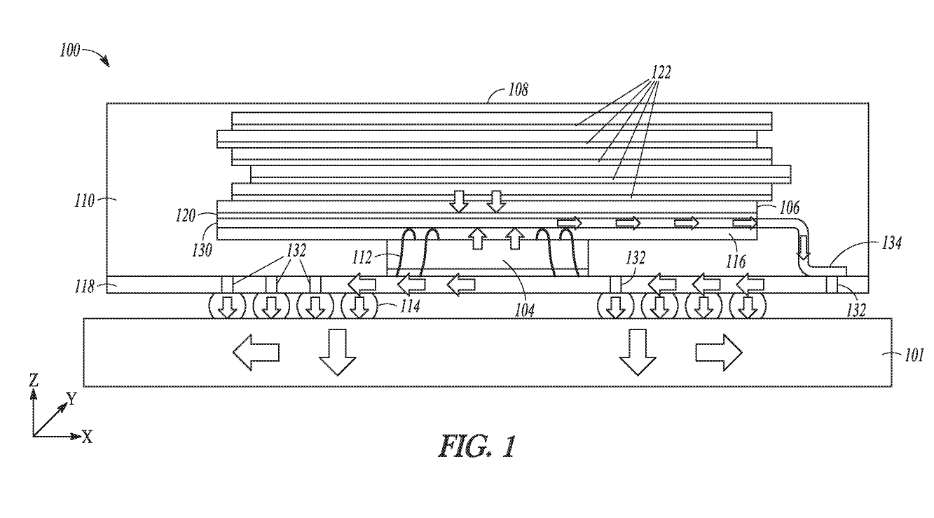

FIG. 1 illustrates an example integrated circuit (IC) package 100, according to various embodiments. In some embodiments, IC package 100 may be a system-in-package. IC package 100 may include one or more dies, such as first die 104 and second die 106.

First die 104 may be mounted to substrate 118, which may be mounted to printed circuit board 101. Substrate 118 extends generally parallel to printed circuit board 101. First die 104 may include an IC to perform one or more particular operations. In some embodiments, first die 104 may be a processor, a controller, an ASIC, a field-programmable gate array, a high-bandwidth memory, a package-embedded memory, a flash memory, an embedded nonvolatile memory, a graphics card, a III-V die, an accelerator, a low power double data, a passive bridge die or some combination thereof. In some examples, first die 104 may be an ASIC die to perform one or more operations associated with an application of IC package 100.

IC package 100 may further include second die 106. Second die 106 may be stacked above first die 104, and located between first die 104 and the second side of IC package 100. Second die 106 may be, for example, a processor, an ASIC, a controller, a field-programmable gate array, a high-bandwidth memory, a package-embedded memory, a random access memory, a flash memory, an embedded nonvolatile memory, a graphics card, a III-V die, an accelerator, or a low power double data.

IC package 100 may further include die stack 108. Die stack 108 may include one or more dies that perform the same or similar operations as the other dies within the die stack 108. Die stack 108 may be stacked above second die 106. Each die in die stack 108 may further be stacked in relation to other dies within die stack 108. In some embodiments, die stack 108 may include, for example, one or more NAND flash memory dies. The dies in stack 108 may also include any combination of other suitable dies such as a controller, a field-programmable gate array, a high-bandwidth memory, a package-embedded memory, a random access memory, a flash memory, an embedded nonvolatile memory, a graphics card, a III-V die, an accelerator, or a low power double data.

While IC package 100 is described as including first die 104, second die 106, and die stack 108, it is to be understood that IC package 100 may include more or fewer dies and/or die stacks in other embodiments. Further, while first die 104, second die 106, and die stack 108 are shown as stacked from a first side of the IC package 100, which may be mounted to printed circuit board 101, toward the second side of the IC package 100, opposite to the first side, it is to be understood that the dies and/or die stacks may be attached to different surfaces in other embodiments. For example in other embodiments, any one of first die 104, second die 106, or die stack 108 may be attached to the second side of the IC package 100. It will be further understood that IC package 100 may take on other configurations, such as one including a third die, in which first die 104 and second die 106 are active dies and the third die is a passive die bridging the first die 104 and the second die 106. The third die may be substantially embedded within substrate 118.

In some embodiments, a spacer such as a die attach film (DAF) may be applied to one or more sides of first die 104, second die 106, and/or one or more dies of die stack 108. For example, first DAF 116 may be applied to first die 104, second DAF 120 may be applied to second die 106, and DAFs 122 may be applied to the dies of die stack 108 (collectively, “the DAB”). DAFs 122 may include die-attach films laminated directly to the dies. In some embodiments, DAFs 122 may include epoxy die attach, die attach paste, die attach tape, and/or some combination thereof. DAFs 122 may provide thermal resistance; however, an amount of thermal resistance provided by DAFs 122 may be limited by a thickness of the DAFs 122, which may range between approximately 5 micrometers and approximately 20 micrometers. All DAFs 116, 120, and 122 are further thermally characterized as isotropic.

IC package 100 may include substrate 118. Substrate 118 may include one or more traces to route electrical signals. Traces of substrate 118 may be coupled to one or more interconnects 114 and may route the electrical signals to and/or from one or more interconnects 114. In the embodiment illustrated, the one or more interconnects 114 include a ball grid array; however, it is to be understood that in other embodiments the one or more interconnects 114 may include a pin grid array, a land grid array, one or more solder balls, one or more wire leads, surface mount contacts, through-hole contacts, or some combination thereof.

IC package 100 may further include one or more wires 112. The wires 112 may couple one or more of first die 104, second die 106, die stack 108, or some combination thereof, to each other. Further, wires 112 may couple one or more of first die 104, second die 106, die stack 108, or some combination thereof, to substrate 118. Accordingly, first die 104, second die 106, die stack 108, or some combination thereof, may be coupled to each other and/or the one or more interconnects 114 via wires 112 and/or substrate 118.

In some embodiments, first die 104 may have a greater operational junction heat threshold value for temperature than second die 106, or vice versa. The operational junction threshold heat value may be a temperature where an operation of a die may undesirably degrade when the temperature of the die exceeds the operational junction threshold temperature. The operational junction threshold temperature for first die 104 and/or second die 106 may be based on a period of a refresh cycle for volatile stored data versus a period of retention of the data before loss of the data for first die 104 and/or second die 106, breakdown of materials within first die 104 and/or second die 106, or some combination thereof. As temperatures of first die 104 and/or second die 106 increase, the period of retention of the data before loss may be decreased based on an increased rate of electrical discharge of storage capacitors (or other storage component) within first die 104 and/or second die 106 due to the temperature increase, and/or the materials may exhibit physical structure changes and/or chemical changes that cause decreased performance of first die 104 and/or second die 106.

Because each die may have a different operational heat threshold value, it may be desirable to reduce the amount of heat transfer between at least first die 104 and second die 106. This may help to prevent first die 104, with the greater operational junction threshold temperature, from heating second die 106, with the lower operational junction threshold temperature, to a temperature greater than the operational junction threshold temperature of the second die 106. One way to accomplish this is to increase DAF 120 thickness between first die 104 and second die 106 by delaying heat transfer from 104 to 106. Heat from second die 106, however, is absorbed by the DAF 120 but eventually is transferred to the first die 104. The thickness of DAF 120 impacts the time it takes for the heat transfer to first die 104 to occur. While increasing the thickness of DAF 120 delays the heat transfer, the z-height, measured along the z-axis (shown in FIG. 1) of IC package 100, is also increased. This may be undesirable in certain circumstances where minimization of IC package 100 is desired (e.g., in mobile phones or tablets).

In embodiments where first die 104 is an ASIC die and second die 106 is a DRAM die, first die 104 may have an operational junction threshold temperature of between approximately 100 and approximately 125 degrees-Celsius, whereas second die 106 may have an operational junction threshold temperature of between approximately 70 and approximately 90 degrees-Celsius. When within normal operation conditions, first die 104 may operate at a temperature, for example, greater than approximately 70 degree-Celsius. Accordingly, it may be beneficial to decrease an amount of heat transfer from the first die 104 to the second die 106 in order to decrease chances that the second die 106 will exceed its operational junction threshold temperature due to heat produced by the first die 104. Positioning a relatively thick (e.g., thicker than first die 104 and/or second die 106) thermally isotropic layer 120 between the first die 104 and the second die 106 may provide this benefit. However, IC package 100 uses a different approach. As shown in FIG. 1, IC package 100 includes anisotropic thermally conductive layer 130 positioned between first die 104 and second die 106.

Anisotropic thermally conductive layer 130 is thermally anisotropic in that a first thermal conductivity of the material in a first direction (indicated by the arrows aligned along the x-axis shown in FIG. 1) is greater than a second thermal conductivity of the material in a second direction. In other words, the heat is conducted in substantially one direction. This direction is in substantially the same direction as the x-y plane of the major surfaces of the first die 104 and the second die 106, (heat conduction is generally depicted by the arrows in FIG. 1)

To provide the anisotropic thermal conductivity, anisotropic thermally conductive layer 130 includes some thermally anisotropic component. The thermally anisotropic component may range from about 50 wt % to about 100 wt %, 70 wt % to 100 wt %, or 90 wt % to 100 wt % of anisotropic thermally conductive layer 130. The thermally anisotropic component may be one of many suitable materials. Examples include carbon nanotubes, carbon fibers, boron fibers, or mixtures thereof. The thermally anisotropic nature of the material may result from the material (e.g., the individual nanotubes or fibers) being aligned in substantially the same direction.

The thermal conductivity of the anisotropic thermally conductive layer 130 in the first direction may range from about 100 watts per milliKelvin (W/mK) to about 5000 W/mK, or from about 200 W/mK to about 4000 W/mK, or from about 300 W/mK to about 3000 W/mK, or from about 400 W/mK to about 3000 W/mK, or from about 500 W/mK to about 2000 W/mK, or from about 600 W/mK to about 3000 W/mK, or from about 700 W/mK to about 2000 W/mK, or from about 800 W/mK to about 1000 W/mK.

The thickness of thermally conductive layer 130 may be relatively thin. This may help to decrease the overall z-height of IC package 100. For example, the thickness of thermally conductive layer 130 may range from about 5 microns to about 10 microns, or from about 6 microns to about 9 microns, or from about 7 microns to about 8 microns.

First DAF 116 may be disposed between anisotropic thermally conductive layer 130 and first die 104. DAF 116 is made from a thermally isotropic material. DAF 116 is not as thick as anisotropic thermally conductive layer 130. This may help to reduce the z-height of IC package 100. For example, DAF 116 may have a thickness ranging from about 0.1 microns to about 3 microns, or from about 0.5 microns to about 2.0 microns, or from about 1 micron to about 1.5 microns.

Similarly second DAF 120 may be disposed between anisotropic thermally conductive layer 130 and second die 106. DAF 120 is made from a thermally isotropic material. DAF 120 is not as thick as anisotropic thermally conductive layer 130. This may help to reduce the z-height of IC package 100. For example, DAF 120 may have a thickness ranging from about 0.1 microns to about 3 microns, or from about 0.5 microns to about 2.0 microns, or from about 1 micron to about 1.5 microns.

DAF 116 and DAF 120 may help to protect anisotropic thermally conductive layer 130 in that they form a barrier between first die 104 and second die 106. Additionally, anisotropic thermally conductive layer 130 is formed from a relatively rigid material. Thus the thermally conductive layer 130 may be load bearing and support first die 104 and second die 106. DAF 116 and DAT 120 may provide mechanical protection on the thermally conductive layer 130 from excess load. Moreover, low modulus of DAF 116 and 120 would compensate CTE (Coefficient of thermal expansion) mismatch of 130 from Die 104 and 120. In some examples thermally conductive layer 130 may be incorporated into DAF 116 or 120.

Substrate 118 is formed from dielectric layers and electrical conducting layers. The dialectic layers are formed from an organic-based dielectric material such as an epoxide. The conducting layers are formed from electronically conducting materials such as copper. Both materials are thermally isotropic. Substrate 118 may include a plurality of vias 132 disposed therein. Vias 132 are formed from copper and may be adapted to conduct electricity, or they may be configured to transfer heat as thermal vias. Thermal vias may be larger in surface area than electronically conducting vias. Thermal vias may be exposed on a surface of substrate 118

Anisotropic thermally conductive layer 130 is connected to and thermally coupled to substrate 118 through extension 134. Heat transferred from first die 104 and second die 106 is transferred through anisotropic thermally conductive layer 130 and extension 134 to substrate 118. Heat transferred to substrate 118 may be dissipated through substrate 118 where there is less risk of causing damage to dies 104 and 106. The heat may further be transferred from substrate 118 to molding compound 110 or through interconnects 114 such as solder balls to printed circuit board 101. In this manner heat does not collect in an isotropic or low conductivity material disposed between first die 104 and second die 106. Instead, heat generated from first die 104 and second die 106 is rapidly transferred away from first die 104 and second die 106 and to a location in IC package 100 where it is less likely to cause any damage.

Anisotropic thermally conductive layer 130 may be connected to many different components of substrate 118. For example, anisotropic thermally conductive layer 130 may be connected directly to a thermal via. The thermal via may have a relatively high heat transfer value and heat may be quickly transported through substrate 118 by way of the thermal via. Anisotropic thermally conductive layer 130 may also be directly connected to an electrical via 132 or a dielectric layer.

Integrated circuit package 100 may be designed to further include a second anisotropic thermally conductive layer. The second anisotropic thermally conductive layer may be adapted to be thermally anisotropic. The second anisotropic thermally conductive layer may be disposed on or between the dies 104, 106 of die stack 108. The second anisotropic thermally conductive layer may also be disposed between second die 106 and a third die. For example, if the third die is a passive bridge die that is connected to first die 104 and second die 106, then the first anisotropic thermally conductive layer 130 and the second anisotropic thermally conductive layer may effectively transfer heat from the third die as well as from the first die 104 and second die 106.

IC package 100 may further include molding compound 110. Molding compound 110 may at least partially encompass first die 104, second die 106, die stack 108, anisotropic thermally conductive layer 130, or some combination thereof, on one or more sides. For example, molding compound 110 may surround first die 104, second die 106, die stack 108, and anisotropic thermally conductive layer 130 on the top and sides, but not on the bottom; on the bottom and sides, but not the top; on the top and the bottom, but not on all the sides; or some combination thereof. In some embodiments, molding compound 110 may encompass first die 104, second die 106, die stack 108, anisotropic thermally conductive layer 130, or some combination thereof, on all sides. The molding compound 110 may be abutted on one side by substrate 118. Molding compound 110 may be rigid and may protect first die 104, second die 106, die stack 108, anisotropic thermally conductive layer 130, or some combination thereof, from damage. Further, molding compound 110 may be an electrical insulator, preventing unintended electrical current transfer, via molding compound 110, among first die 104, second die 106, die stack 108, substrate 118, or some combination thereof.

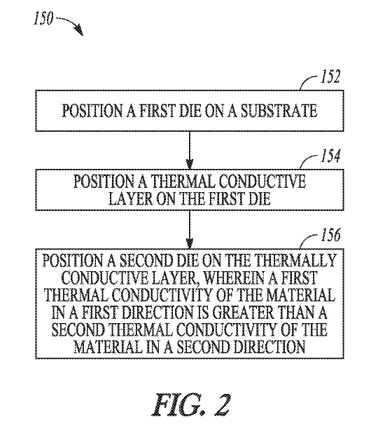

A method of forming integrated circuit package 100 is shown in FIG. 2. Method 150 may include operation 152, which includes positioning first die 104 on substrate 118. Method 150 may include operation 154, in which anisotropic thermally conductive layer 130 is then positioned on first die 104. Method 150 may further include operation 156, in which second die 106 is positioned on anisotropic thermally conductive layer 130. Anisotropic thermally conductive layer 130 may be attached to first die 104 and second die 106 through a die attachment film. Anisotropic thermally conductive layer 130 may be pressed to the die attachment layer. Additionally, thermally conductive layer 130 is attached to at least one of a dielectric layer of substrate 118, an electrical conducting layer of substrate 118, or a thermal via of substrate 118. Wires 112 may he used to electronically connect substrate 118 and second die 106. In some examples die stack 108 is attached to second die 106.

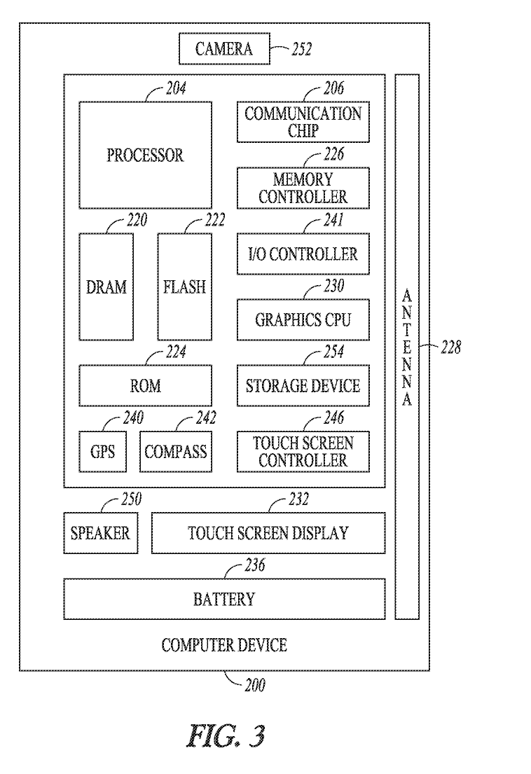

FIG. 3 illustrates an example computer device 200 that may employ the apparatuses and/or methods described herein (e.g., the IC package 100), in accordance with various embodiments. As shown, computer device 200 may include a number of components, such as one or more processor(s) 204 (one shown) and at least one communication chip 206. In various embodiments, the one or more processor(s) 204 each may include one or more processor cores. In various embodiments, the at least one communication chip 206 may be physically and electrically coupled to the one or more processor(s) 204. In further implementations, the communication chip 206 may be part of the one or more processor(s) 204. In various embodiments, computer device 200 may include printed circuit board (e.g., printed circuit board 101) 202. For these embodiments, the one or more processor(s) 204 and communication chip 206 may be disposed thereon. In alternate embodiments, the various components may be coupled without the employment of printed circuit board 202.

Depending on its applications, computer device 200 may include other components that may or may not be physically and electrically coupled to the printed circuit board 202. These other components include, but are not limited to, memory controller 226, volatile memory (e.g., dynamic random access memory (DRAM) 220), non-volatile memory such as read only memory (ROM) 224, flash memory 222, storage device 254 (e.g., a hard-disk drive (HDD)), an I/O controller 241, a digital signal processor (not shown), a crypto processor (not shown), a graphics processor 230, one or more antenna 228, a display (not shown), a touchscreen display 232, a touchscreen controller 246, a battery 236, an audio codec (not shown), a video codec (not shown), a global positioning system (GPS) device 240, a compass 242, an accelerometer (not shown), a gyroscope (not shown), a speaker 250, a camera 252, and a mass storage device (such as hard disk drive, a solid state drive, compact disk (CD), digital versatile disk (DVD)) (not shown), and so forth.

In some embodiments, the one or more processor(s) 204, flash memory 222, and/or storage device 254 may include associated firmware (not shown) storing programming instructions configured to enable computer device 200, in response to execution of the programming instructions by one or more processor(s) 204, to practice all or selected aspects of the methods described herein. In various embodiments, these aspects may additionally or alternatively be implemented using hardware separate from the one or more processor(s) 204, flash memory 222, or storage device 254.

In various embodiments, one or more components of the computer device 200 may include the IC package 100.

The communication chips 206 may enable wired and/or wireless communications for the transfer of data to and from the computer device 200. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 206 may implement any of a number of wireless standards or protocols, including but not limited to IEEE 802.20, Long Term Evolution (LIE), LTE Advanced (LTE-A), General Packet Radio Service (CPRS), Evolution Data Optimized (Ev-DO), Evolved High Speed Packet Access (HSPA+), Evolved High Speed Downlink Packet Access (HSDPA+), Evolved High Speed Uplink Packet Access (HSIJPA+), Global System for Mobile Communications (GSM), Enhanced Data rates for GSM Evolution (EDGE), Code Division Multiple Access (CDMA), Time Division Multiple Access (TDMA), Digital Enhanced Cordless Telecommunications (DECT), Worldwide Interoperability for Microwave Access (WiMAX), Bluetooth, derivatives thereof, as well as any other wireless protocols that are designated as 3G, 4G, 5G, and beyond. The computer device 200 may include a plurality of communication chips 206. For instance, a first communication chip 206 may be dedicated to shorter range wireless communications such as Wi-Fi and Bluetooth, and a second communication chip 206 may be dedicated to longer range wireless communications such as GPS, EDGE, GPRS, CDMA, WiMAX, LTE. Ev-DO, and others.

In various implementations, the computer device 200 may be a laptop, a netbook, a notebook, an ultrabook, a smartphone, a computer tablet, a personal digital assistant (PDA), an ultra-mobile PC, a mobile phone, a desktop computer, a server, a printer, a smayner, a monitor, a set-top box, an entertainment control unit (e.g., a gaming console or automotive entertainment unit), a digital camera, an appliance, a portable music player, or a digital video recorder. In further implementations, the computer device 200 may be any other electronic device that processes data.

It will be apparent to those skilled in the art that various modifications and variations may be made in the disclosed embodiments of the disclosed device and associated methods without departing from the spirit or scope of the disclosure. Thus, it is intended that the present disclosure covers the modifications and variations of the embodiments disclosed above provided that the modifications and variations come within the scope of any claims and their equivalents.

### Additional Embodiments,

The following exemplary embodiments are provided, the numbering of which is not to be construed as designating levels of importance:

Embodiment 1 provides an integrated circuit package comprising:

a substrate;

a first die attached to the substrate;

a second die; and

a thermally conductive layer disposed between the first die and the second die, wherein a first thermal conductivity of the material in a first direction is greater than a second thermal conductivity of the material in a second direction.

Embodiment 3 provides the integrated circuit package of Embodiment 2, wherein the first spacer layer comprises a die attachment film.

Embodiment 4 provides the integrated circuit package of any one of Embodiments 2 or 3, wherein the first spacer layer comprises silicate glass or glass fiber.

Embodiment 5 provides the integrated circuit package of any one of Embodiments 2-4, wherein a thickness of the first spacer layer ranges from about 0.1 microns to about 3 microns.

Embodiment 6 provides the integrated circuit package of any one of Embodiments 2-5, wherein a thickness of the first spacer layer ranges from about 1.5 microns to about 2 microns.

Embodiment 7 provides the integrated circuit package of any one of Embodiments 2-6, further comprising a second spacer layer disposed between the thermally conductive material and the second die.

Embodiment 8 provides the integrated circuit package of Embodiment 7, wherein the second spacer layer is a die attachment film.

Embodiment 9 provides the integrated circuit package of any one of Embodiments 7 or 8, wherein a thickness of the second spacer layer ranges from about 0.1 microns to about 3 microns.

Embodiment 10 provides the integrated circuit package of any one of Embodiments 7-9, wherein a thickness of the second spacer layer ranges from about 1.5 microns to about 2 microns.

Embodiment 11 provides the integrated circuit package of any one of Embodiments 7-10, wherein the second spacer layer is a silicate glass or glass fiber.

Embodiment 12 provides the integrated circuit package of any one of Embodiments 1-11, wherein the thermally conductive layer comprises an anisotropic component distributed within the thermally conductive layer,

Embodiment 13 provides the integrated circuit package of Embodiment 12, wherein the anisotropic component is about 50 wt % to about 100 wt % of the thermally conductive layer.

Embodiment 14 provides the integrated circuit package of any one of Embodiments 12 or 13, wherein the anisotropic component is about 90 wt % to about 100 wt % of the thermally conductive layer.

Embodiment 15 provides the integrated circuit package of any one of Embodiments 12-14, wherein the anisotropic component comprises carbon nanotubes, carbon fibers, boron fibers, or mixtures thereof, wherein a microstructure of the anisotropic component is aligned in substantially the same direction.

Embodiment 16 provides the integrated circuit package of any one of Embodiments 1-15, wherein the thermal conductivity in the first direction ranges from about 100 W/mK to about 5000 W/mK.

Embodiment 17 provides the integrated circuit package of any one of Embodiments 1-16, wherein the thermal conductivity in the first direction ranges from about 500 W/mK to about 3500 W/mK.

Embodiment 18 provides the integrated circuit package of any one of Embodiments 1-17, wherein the first direction is substantially aligned with an x-y direction plane defined by aligned major surfaces of the first die and second die.

Embodiment 19 provides the integrated circuit package of any one of Embodiments 1-18, wherein a thickness of the thermally conductive layer ranges from about 5 microns to about 10 microns.

Embodiment 20 provides the integrated circuit package of any one of Embodiments 1-19, wherein a thickness of the thermally conductive layer ranges from about 5 microns to about 7 microns.

Embodiment 21 provides the integrated circuit package of any one of Embodiments 1-20, wherein the substrate is formed from dielectric layers and electrical conducting layers.

Embodiment 22 provides the integrated circuit package of any one of Embodiments 1-21, wherein the dielectric layers are formed from a dielectric material.

Embodiment 23 provides the integrated circuit package of any one of Embodiments 1-22, wherein the electrical conducting layers is formed from an electrically conducting material.

Embodiment 24 provides the integrated circuit package of any one of Embodiments 1-23, wherein the electrically conducting material is copper.

Embodiment 25 provides the integrated circuit package of any one of Embodiments 1-24, further comprising a plurality of vias disposed within the substrate.

Embodiment 26 provides the integrated circuit package of any one of Embodiments 1-25, wherein the vias are formed from copper.

Embodiment 27 provides the integrated circuit package of any one of Embodiments 1-26, wherein one of the vias is a thermal via.

Embodiment 28 provides the integrated circuit package of any one of Embodiments 1-27, wherein the thermally conductive layer is thermally coupled to the substrate.

Embodiment 29 provide the integrated circuit package of Embodiment 28, wherein the thermally conductive layer is connected to at least one of the dielectric layer, the electrical conducting layer, and the thermal via.

Embodiment 30 provides the integrated circuit package of any one of Embodiments 1-29, wherein the first die is a processor, an application specific integrated circuit, field-programmable gate array, a high-bandwidth memory, a package embedded memory, a flash memory, an embedded nonvolatile memory, a graphics card a III-V die, an accelerator, or a low power double data.

Embodiment 31 provides the integrated circuit package of any one of Embodiments 1-30, wherein the second die is a processor, an application specific integrated circuit, field-programmable gate array, a high-bandwidth memory, a package embedded memory, a random access memory, a flash memory, an embedded nonvolatile memory, a graphics card a III-V die, an accelerator, or a low power double data.

Embodiment 32 provides the integrated circuit package of any one of Embodiments 1-31, further comprising a die stack formed from a plurality of dies.

Embodiment 33 provides the integrated circuit package of Embodiment 32, wherein the die stack is a NAND flash memory stack.

Embodiment 34 provides the integrated circuit package of any one of Embodiments 1-33, where each of the plurality of dies are separated by a die attachment film.

Embodiment 35 provides the integrated circuit package of any one of Embodiments 1-34, wherein the thermally conductive layer is at least partially incorporated within a die attachment film disposed between at least one of the substrate, the first die, and the second die.

Embodiment 36 provides the integrated circuit package of any one of Embodiments 1-34, further comprising a second thermally conductive layer disposed on one of the of dies of the die stack, wherein a first thermal conductivity of the material in a first direction is greater than a second thermal conductivity of the material in a second direction.

Embodiment 37 provides the integrated circuit package of any one of Embodiments 1-36, wherein the second die is a passive bridge die.

Embodiment 38 provides the integrated circuit package of Embodiment 37, wherein the bridge die is embedded in the substrate.

Embodiment 39 provides the integrated circuit package of any one of Embodiments 1-38, further comprising a third die attached to the bridge die.

Embodiment 40 provides the integrated circuit package of Embodiment 39, further comprising a second thermally conductive layer disposed between the second die and third die, wherein a first thermal conductivity of the material in a first direction is greater than a second thermal conductivity of the material in a second direction.

Embodiment 41 provides the integrated circuit package of any one of Embodiments 1-40, further comprising a molding compound that at least partially encapsulates the first die and the second die.

Embodiment 42 provides an electronic device comprising:
a package comprising:
   a substrate;
   a first die attached to the substrate;
   a second die; and
   a thermally conductive layer disposed between the first die and the second die, wherein a first thermal conductivity of the layer in a first direction is greater than a second thermal conductivity of the layer in a second direction; and
a printed circuit board connected to the package.

Embodiment 43 provides the electronic device of Embodiment 42, further comprising:

solder halls connecting the package and the printed circuit board.

Embodiment 44 provides the electronic device of any one of Embodiments 42 or 43, further comprising a first spacer layer between the thermally conductive material and the first die.

Embodiment 45 provides the electronic device of Embodiment 44, wherein the first spacer layer comprises a die attachment film.

Embodiment 46 provides the electronic device of any one of Embodiments 44 or 45, wherein the first spacer layer comprises silicate glass or glass fiber.

Embodiment 47 provides the electronic device of any one of Embodiments 44-46, wherein a thickness of the first spacer layer ranges from about 0.1 microns to about 3 microns.

Embodiment 48 provides the electronic device of any one of Embodiments 44-47, wherein a thickness of the first spacer layer ranges from about 1.5 microns to about 2 microns.

Embodiment 49 provides the electronic device of any one of Embodiments 44-48, further comprising a second spacer layer disposed between the thermally conductive material and the second die.

Embodiment 50 provides the electronic device of any one of Embodiments 44-49, wherein the second spacer layer is a die attachment film,

Embodiment 51 provides the electronic device of any one of Embodiments 42-50, wherein a thickness of the second spacer layer ranges from about 0.1 microns to about 3 microns.

Embodiment 52 provides the electronic device of any one of Embodiments 42-51, wherein a thickness of the second spacer layer ranges from about 1.5 microns to about 2 microns.

Embodiment 53 provides the electronic device of any one of Embodiments 42-52, wherein the second spacer layer is a silicate glass or glass fiber.

Embodiment 54 provides the electronic device of any one of Embodiments 42-53, wherein the thermally conductive layer comprises an anisotropic component.

Embodiment 55 provides the electronic device of Embodiment 54, wherein the anisotropic component is about 50 wt % to about 100 wt % of the thermally conductive layer.

Embodiment 56 provides the electronic device of any one of Embodiments 54 or 55, wherein the anisotropic component is about 90 wt % to about 100 wt % of the thermally conductive layer.

Embodiment 57 provides the electronic device of any one of Embodiments 54-56, wherein the anisotropic component comprises carbon nanotubes, carbon fibers, boron fibers, or mixtures thereof.

Embodiment 58 provides the electronic device of any one of Embodiments 54-57, wherein a microstructure of the anisotropic component is aligned in substantially the same direction.

Embodiment 59 provides the electronic device of any one of Embodiments 42-58, wherein the thermal conductivity in the first direction ranges from about 100 W/mK to about 5000 W/mK.

Embodiment 60 provides the electronic device of any one of Embodiments 42-59, wherein the thermal conductivity in the first direction ranges from about 500 W/mK to about 3500 W/mK.

Embodiment 61 provides the electronic device of any one of Embodiments 42-60, wherein the first direction is substantially aligned with an x-y direction plane defined by aligned major surfaces of the first die and second die.

Embodiment 62 provides the electronic device of any one of Embodiments 42-61, wherein a thickness of the thermally conductive layer ranges from about 5 microns to about 10 microns.

Embodiment 63 provides the electronic device of any one of Embodiments 42-62, wherein a thickness of the thermally conductive layer ranges from about 5 microns to about 7 microns.

Embodiment 64 provides the electronic device of any one of Embodiments 42-63, wherein the substrate is formed from dielectric layers and electrical conducting layers.

Embodiment 65 provides the electronic device of any one of Embodiments 42-64, wherein the dielectric layers are formed from a dielectric material.

Embodiment 66 provides the electronic device of any one of Embodiments 42-65, wherein the electrical conducting layers is formed from an electrically conducting material.

Embodiment 67 provides the electronic device of any one of Embodiments 42-66, wherein the electrically conducting material is copper.

Embodiment 68 provides the electronic device of any one of Embodiments 42-67, further comprising a plurality of vias disposed within the substrate.

Embodiment 69 provides the electronic device of any one of Embodiments 42-68, wherein the vias are formed from copper.

Embodiment 70 provides the electronic device of any one of Embodiments 42-69, wherein one of the vias is a thermal via.

Embodiment 71 provides the electronic device of any one of Embodiments 42-70, wherein the thermally conductive layer is connected to the substrate.

Embodiment 72 provide the electronic device of any one of Embodiments 70 or 71, wherein the thermally conductive layer is connected to at least one of the dielectric layer, the electrical conducting layer, and the thermal via.

Embodiment 73 provides the electronic device of any one of Embodiments 42-72, wherein the first die is a processor, an application specific integrated circuit, field-programmable gate array, a high-bandwidth memory, a package embedded memory, a flash memory, an embedded nonvolatile memory, a graphics card a III-V die, an accelerator, or a low power double data.

Embodiment 74 provides the electronic device of any one of Embodiments 42-73, wherein the second die is a processor, an application specific integrated circuit, field-programmable gate array, a high-bandwidth memory, a package embedded memory, a random access memory, a flash memory, an embedded nonvolatile memory, a graphics card a III-V die, an accelerator, or a low power double data.

Embodiment 75 provides the electronic device of any one of Embodiments 42-74, further comprising a die stack formed from a plurality of dies.

Embodiment 76 provides the electronic device of Embodiment 75, wherein the die stack is a NAND flash memory stack.

Embodiment 77 provides the electronic device of any one of Embodiments 42-76, where each of the plurality of dies are separated by a die attachment film.

Embodiment 78 provides the electronic device of any one of Embodiments 42-77, further comprising a second thermally conductive layer disposed on one of the pluralities of dies of the die stack, wherein a first thermal conductivity of the material in a first direction is greater than a second thermal conductivity of the material in a second direction.

Embodiment 79 provides the electronic device of Embodiment 78, wherein the second die is a passive bridge die.

Embodiment 80 provides the electronic device of Embodiment 79, wherein the bridge die is embedded in the substrate.

Embodiment 81 provides the electronic device of any one of Embodiments 79 or 80, further comprising a third die attached to the bridge die.

Embodiment 82 provides the electronic device of Embodiment 81, further comprising a second thermally conductive layer disposed between the second die and third die, wherein a first thermal conductivity of the material in a first direction is greater than a second thermal conductivity of the material in a second direction.

Embodiment 83 provides the electronic device of any one of Embodiments 42-82, further comprising a molding compound that at least partially encapsulates the first die and the second die.

Embodiment 84 provides a method of forming an integrated circuit package comprising:

positioning a first die on a substrate;

positioning a thermally conductive layer on the first die; and

positioning a second die on the thermally conductive layer, wherein a first thermal conductivity of the layer in a first direction is greater than a second thermal conductivity of the layer in a second direction.

Embodiment 85 provides the method of Embodiment 84, further comprising attaching the thermally conductive material to the substrate.

Embodiment 86 provides the method of any one of Embodiments 84 or 85, wherein the thermally conducting material is attached to at least one of a dielectric layer of the substrate, an electrical conducting layer of the substrate, and a thermal via of the substrate.

Embodiment 87 provides the method of any one of Embodiments 84-86, wherein the thermally conductive material is attached to a die.

Embodiment 88 provides the method of any one of Embodiments 84-87, further comprising attaching e first die to the substrate with a first die attachment film.

Embodiment 89 provides the method of any one of Embodiments 84-88, further comprising attaching the thermally conductive layer to the first die with a second die attachment film.

Embodiment 90 provides the method of any one of Embodiments 84-89, further comprising attaching the thermally conductive layer to the second die with a third die attachment film.

Embodiment 91 provides the method of any one of Embodiments 84-90, further comprising attaching wires from the substrate and the second die.

Embodiment 92 provides the method of any one of Embodiments 84-91, further composing attaching a die stack to the second die.

Embodiment 93 provides the method of any one of Embodiments 84-92, further comprising attaching the die stack to the second die with a fourth attachment film.

1. An integrated circuit package comprising:
a substrate;
a thermal via disposed at least partially within the substrate
a first die attached to the substrate;
a second die; and
a thermally conductive layer disposed between the first die and the second die, wherein a first thermal conductivity of the layer in a first direction is greater than a second thermal conductivity of the layer in a second direction, a portion of the thermally conductive layer contacting the thermal via.

2. The integrated circuit package of claim 1, wherein the thermally conductive layer comprises an anisotropic component distributed within the thermally conductive layer.

3. The integrated circuit package of claim 2, wherein the anisotropic component is about 50 wt % to about 100 wt % of the thermally conductive layer.

4. The integrated circuit package of claim 2, wherein the anisotropic component is about 90 wt % to about 100 wt % of the thermally conductive layer.

5. The integrated circuit package of claim 2, wherein the anisotropic component comprises carbon nanotubes, carbon fibers, boron fibers, or mixtures thereof, wherein a microstructure of the anisotropic component is aligned in substantially the same direction

6. The integrated circuit package of claim 2, wherein the thermally conductive layer is thermally coupled to the substrate.

7. The integrated circuit package of claim 1, wherein the first thermal conductivity in the first direction ranges from about 100 W/mK to about 5000 W/mK.

8. The integrated circuit package of claim 1, wherein the thermally conductive layer is at least partially incorporated within a die attachment film disposed between at least one of the substrate, the first die, and the second die.

9. The integrated circuit package of claim 1, wherein the first direction is substantially aligned with an x-y direction plane defined by aligned major surfaces of the first die and second die.

10. The integrated circuit package of claim 1, wherein a thickness of the thermally conductive layer ranges from about 5 microns to about 10 microns.

11. An electronic device comprising:
a package comprising:
a substrate;
a thermal via disposed at least partially within the substrate;
a first die attached to the substrate;
a second die; and
a thermally conductive layer disposed between the first die and the second die, wherein a first thermal conductivity of the layer in a first direction is greater than a second thermal conductivity of the layer in a second direction, a portion of the thermally conductive layer contacting the thermal via; and
a printed circuit board connected to the package.

12. The electronic device of claim 11, further comprising:
solder balls connecting the package and the printed circuit board.

13. The electronic device of claim of claim 11, wherein the thermally conductive layer comprises an anisotropic component.

14. The electronic device of claim of claim 11, wherein the first die is a processor, an application specific integrated circuit, field-programmable gate array, a high-bandwidth memory, a package-embedded memory, a flash memory, an embedded nonvolatile memory, a graphics card, a III-V die, an accelerator, or a low power double data.

15. The electronic device of claim of claim 11, wherein the second die is a processor, an application specific integrated circuit, field-programmable gate array a high-bandwidth memory, a package-embedded memory, a random access memory, a flash memory, an embedded nonvolatile memory, a graphics card, a die, an accelerator, or a low power double data.

16. The electronic device of claim of claim 11, further comprising a die stack formed from a plurality of dies.

17. A method of forming an integrated circuit package comprising:
positioning a first die on a substrate, the substrate comprising a thermal via;
positioning a thermally conductive layer on the first die and in contact with a portion of the thermal via; and
positioning a second die on the thermally conductive layer, wherein a first thermal conductivity of the layer in a first direction is greater than a second thermal conductivity of the layer in a second direction.

18. The method of claim 17, further comprising attaching the thermally conductive layer to the substrate.

19. The method of claim 18, wherein the thermally conductive layer is further attached to at least one of a dielectric layer of the substrate, an electrical conducting layer of the substrate, and a thermal via of the substrate.

20. The method of claim 18, wherein the thermally conductive layer is further attached to a die.
